(19) United States
(12) Patent Application Publication
(10) Pub. No.: US 2015/0016205 A1
(43) Pub. Date: Jan. 15, 2015

(54) SEMICONDUCTOR CIRCUIT

(71) Applicant: KABUSHIKI KAISHA TOSHIBA, Tokyo (JP)

(72) Inventors: Masatoshi KOHNO, Saitama (JP); Masami MASUDA, Kanagawa (JP); Mikihiko ITO, Tokyo (JP); Masaru KOYANAGI, Tokyo (JP)

(73) Assignee: KABUSHIKI KAISHA TOSHIBA, Tokyo (JP)

(21) Appl. No.: 14/189,923

(22) Filed: Feb. 25, 2014

(30) Foreign Application Priority Data
Jul. 9, 2013 (JP) 2013-143835

(51) Int. Cl. H03F 3/45; G11C 5/14

(52) U.S. Cl. CPC H03F 3/45071; G11C 5/147
USPC 365/226; 330/252

(57) ABSTRACT

A semiconductor circuit includes a first input section into which a first input signal is inputted, a second input section into which a second input signal is inputted, an output generation circuit which is connected to the first and second input sections and generates an output signal based on the input signals, an output section which outputs the output signal, and a current source which is connected to connection nodes between the input sections and the output generation circuit.

### CROSS-REFERENCE TO RELATED APPLICATION

This application is based upon and claims the benefit of priority from Japanese Patent Application No. 2013-143835, filed Jul. 9, 2013, the entire contents of which are incorporated herein by reference.

### FIELD

Embodiments described herein relate generally to a semiconductor circuit.

### BACKGROUND

Semiconductor circuits have been used in various electronic equipments such as computers, storage devices, and vehicle-mounted control chips.

These semiconductor circuits are required to satisfy the demand for reduction in chip size, enhancement of operational characteristics, reduction of power consumption, and the like.

### DESCRIPTION OF THE DRAWINGS

FIG. 1 is a view schematically showing a semiconductor circuit of an embodiment.

FIG. 2 is an equivalent circuit diagram showing a configuration example of the semiconductor circuit of the embodiment.

FIG. 3 is a flowchart showing an operational example of the semiconductor circuit of the embodiment.

FIG. 4 is a block diagram showing an application example of the semiconductor circuit of the embodiment.

### DETAILED DESCRIPTION

Embodiments provide a technique which enhances an operation speed of a semiconductor circuit.

In general, according to one embodiment, a semiconductor circuit includes: a first input section into which a first input signal is inputted; a second input section into which a second input signal is inputted; an output generation circuit which is connected to the first and second input sections and generates an output signal based on the first and second input signals; an output section which outputs the output signal; and a plurality of current sources which are respectively connected to a connection node between the first input section and the output generation circuit and to a connection node between the second input section and the output generation circuit.

### Embodiment

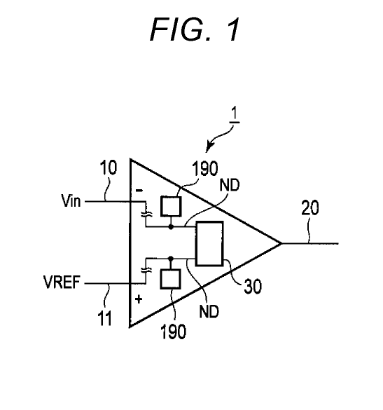

Hereinafter, this embodiment is explained in detail with reference to FIG. 1 to FIG. 4. In the explanation made hereinafter, elements having identical functions and constitutions are given the same symbols, and their repeated explanation is made only as needed.

### (1) Configuration Example

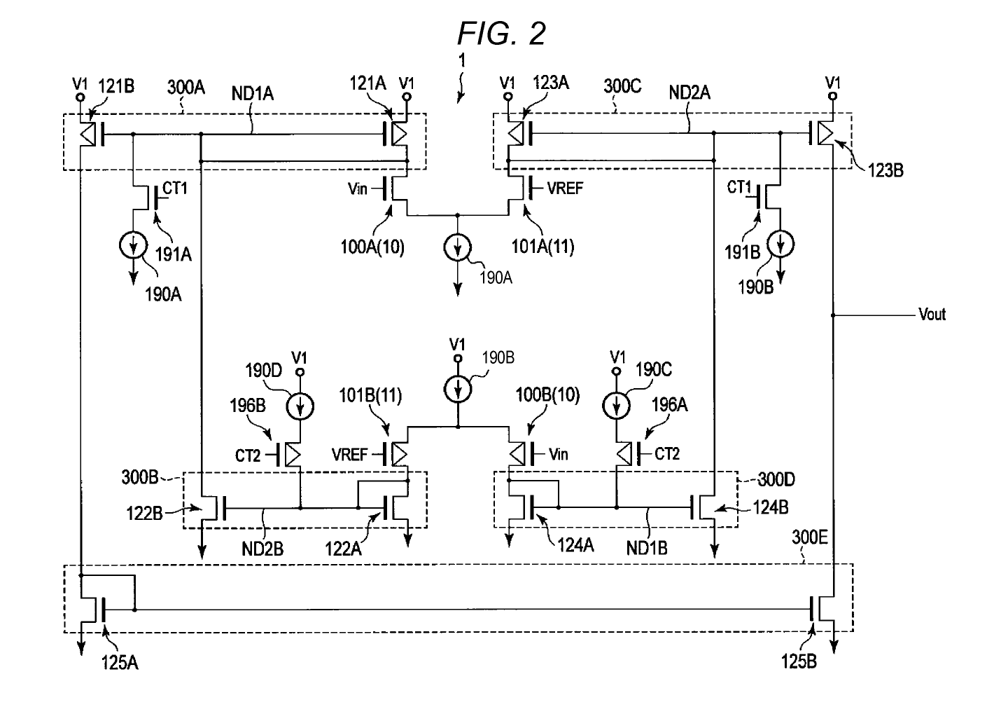

The configuration of an amplifier circuit of the embodiment is explained by reference to FIG. 1 and FIG. 2.

FIG. 1 is a schematic view showing a configuration example of the amplifier circuit of the embodiment. FIG. 2 is an equivalent circuit diagram showing the amplifier circuit of the embodiment.

As shown in FIG. 1, an amplifier circuit 1 of this embodiment includes a first input section 10 into which an input signal Vin is inputted, and a second input section 11 into which a reference signal VREF is inputted. The amplifier circuit 1 of this embodiment includes an output generation circuit 30 for generating an output signal Vout from the input signal Vin and the reference signal VREF. The amplifier circuit 1 of this embodiment includes an output section 20 from which the output signal Vout generated by the output generation circuit 30 is outputted.

In the amplifier circuit 1 of this embodiment, current sources 190 are connected to inner nodes ND which connect the input sections 10, 11 with the output generation circuit 30 respectively. When the amplifier circuit 1 is shifted to an operating state from a standby state, the inner nodes of the amplifier circuit 1 are brought into a charged state or a discharged state by the current sources 190.

The standby state of the amplifier circuit 1 is a state before a power source is applied (or a state immediately after the power source is applied), a state before a drive voltage V1 is applied to the amplifier circuit, or an operating state before the amplifier circuit 1 generates the output signal Vout from the input signal Vin such as a state before the input signal Vin is inputted.

As shown in FIG. 2, as one example of the amplifier circuit 1, the first input section 10 includes an N-channel-type field effect transistor 100A and a P-channel-type field effect transistor 100B, and the second input section 11 includes an N-channel-type field effect transistor 101A and a P-channel-type field effect transistor 101B. Hereinafter, the N-channel-type field effect transistor is referred to as an N-type transistor, and the P-channel-type field effect transistor is referred to as a P-type transistor. The field effect transistor is a MOS transistor, for example.

In the amplifier circuit 1, a gate of the N-type transistor 100A and a gate of the P-type transistor 100B are used as the first input sections 10 of the amplifier circuit 1. The input signal Vin is supplied to the gate of the N-type transistor 100A and the gate of the P-type transistor 100B.

In the amplifier circuit 1, a gate of the N-type transistor 101A and a gate of the P-type transistor 101B are used as the second input sections 11 of the amplifier circuit 1. The reference signal VREF is supplied to the gate of the N-type transistor 101A and the gate of the P-type transistor 101B.

One end of a current path of the N-type transistor 100A of the first input section 10 is connected to a node to which a drive voltage V1 is applied (hereinafter, referred to as a power source line) via a current path of a P-type transistor 121A. One end of a current path of the N-type transistor 101A of the second input section 11 is connected to the power source line via a current path of a P-type transistor 123A. The P-type transistor 121A functions as a load (a load transistor) with respect to the N-type transistor 100A of the input section 10, and the P-type transistor 123A functions as a load with respect to the N-type transistor 101A of the input section 11.

The other end of the current path of the N-type transistor 100A of the input section 10 and the other end of the current path of the N-type transistor 101A of the input section 11 are connected to an input node of a current source 190A. An output node of the current source 190A is connected to a node to which a ground voltage is applied (hereinafter, referred to as a ground line).

One end of a current path of the P-type transistor 100B of the first input section 10 is connected to the ground line via a current path of an N-type transistor 124A. One end of a current path of the P-type transistor 101B of the second input section 11 is connected to the ground line via a current path of an N-type transistor 122A. The N-type transistor 122A functions as a load (a load transistor) with respect to the P-type transistor 100B of the input section 10, and the N-type transistor 124A functions as a load (a load transistor) with respect to the P-type transistor 101B of the input section 11.

The other end of the current path of the P-type transistor 100B of the input section 10 and the other end of the current path of the P-type transistor 101B of the input section 11 are connected to an output node of a current source 190B. An input node of the current source 190B is connected to a power source line, and the drive voltage V1 is applied to the current source 190B.

The N-type transistor 100A and the N-type transistor 101A constitute a differential input section (differential circuit), and the P-type transistor 100B and the P-type transistor 101B constitute a differential input section (differential circuit). In this manner, the amplifier circuit includes the differential input sections so that the amplifier circuit 1 functions as a differential amplifier circuit.

For example, a potential of the reference signal VREF is set to an intermediate value between a potential of an “H” level which is inputted as the input signal Vin and a potential of an “L” level which is inputted as the input signal Vin.

When the drive voltage V1 of the amplifier circuit is 3.3V, for example, a potential corresponding to the input signal Vin of an “H” level is approximately 3.3V, and a potential of the reference signal VREF is approximately 1.65V. A potential corresponding to the input signal Vin of an “L” level is approximately 0V, for example. A potential of the input signal Vin and the potential of the reference signal VREF are suitably changed corresponding to the specification of the amplifier circuit 1 and the specification of a semiconductor circuit including the amplifier circuit. For example, the drive voltage V1 may be set to approximately 1.8V.

The amplifier circuit 1 of this embodiment is a current mirror type differential amplifier circuit.

The output generation circuit 30 of the amplifier circuit 1 of this embodiment includes a plurality of current mirror circuits. For example, in this embodiment, the output generation circuit 30 is formed of five current mirror circuits 300A, 300B, 300C, 300D, 300E.

The current mirror circuit 300A is formed of the P-type transistor 121A and a P-type transistor 121B. The current mirror circuit 300A formed of the P-type transistor 121A and the P-type transistor 121B is connected to the N-type transistor 100A of the first input section 10.

The P-type transistor 121A is diode-connected such that a gate of the P-type transistor 121A is connected to one end of the current path of the P-type transistor 121A. The gate of the P-type transistor 121A is connected to a gate of the P-type transistor 121B. Anode (input node) ND1A of the current mirror circuit 300A is formed of the gates of two P-type transistors 121A, 121B which are connected to each other. The other end of the current path of the P-type transistor 121A is connected to the drive voltage V1, and the other end of the current path of the P-type transistor 121B is connected to the drive voltage V1.

One end of the current path of the N-type transistor 100A of the first input section 10 is connected to one end of the current path of the P-type transistor 121A, and is also connected to the gates (node ND1A) of the P-type transistors 121A, 121B which are connected to each other.

A magnitude of a reference current for the current mirror circuit 300A is changed corresponding to a drive state of the N-type transistor 100A. The current mirror circuit 300A outputs an electric current corresponding to the reference current.

The current mirror circuit 300B is formed of the N-type transistor 122A and an N-type transistor 122B. The current mirror circuit 300B formed of the N-type transistor 122A and the N-type transistor 122B is connected to the P-type transistor 101B of the second input section 11.

One end of the current path of the N-type transistor 122A is connected to one end of the P-type transistor 101B. The other end of the N-type transistor 122A is connected to the ground. The N-type transistor 122A is diode-connected such that one end of the current path of the N-type transistor 122A is connected to agate of the N-type transistor 122A. The other end of the current path of the N-type transistor 122B is connected to the ground.

The gate of the N-type transistor 122A is connected to a gate of the N-type transistor 122B. The gates of two N-type transistors 122A, 122B are connected to each other thus forming a node (input node) ND2B of the current mirror circuit 300B.

One end of the current path of the P-type transistor 101B of the second input section 11 is connected to one end of the current path of the N-type transistor 122A, and is also connected to the gates (node ND2B) of the N-type transistors 122A, 122B which are connected to each other.

A magnitude of a reference current for the current mirror circuit 300B is changed corresponding to a drive state of the P-type transistor 101B. The current mirror circuit 300B outputs an electric current corresponding to the reference current.

One end of the current path of the N-type transistor 122B which constitutes an output node of the current mirror circuit 300B is connected to the node (input node) ND1A of the current mirror circuit 300A, that is, is connected to the gates of two P-type transistors 121A, 121B. An output current of the current mirror circuit 300B is supplied to the current mirror circuit 300A as a section of a reference current for the current mirror circuit 300A together with an electric current from the transistor 101B of the input section 11.

The current mirror circuit 300C is formed of the P-type transistor 123A and a P-type transistor 123B. The current mirror circuit 300C formed of the P-type transistors 123A, 123B is connected to the N-type transistor 101A of the second input section 11.

A gate of the P-type transistor 123A is connected to a gate of the P-type transistor 123B. Anode ND2A of the current mirror circuit 300C is formed of the gates of two P-type transistors 123A, 123B which are connected to each other.

The P-type transistor 123A is diode-connected such that one end of the current path of the P-type transistor 123A is connected to a gate of the P-type transistor 123A.

One end of the current path of the N-type transistor 101A of the second input section 11 is connected to one end of the current path of the P-type transistor 123A, and is also connected to the gates of the P-type transistors 123A, 123B which are connected to each other. The other end of the P-type transistor 123A and the other end of the P-type transistor 123B are connected to the power source line.

A magnitude of a reference current for the current mirror circuit 300C is determined corresponding to a drive state of the N-type transistor 101A. The current mirror circuit 300C outputs an electric current which corresponds to the reference current.

The current mirror circuit 300D is formed of the N-type transistor 124A and an N-type transistor 124B. The P-type transistor 100B of the first input section 10 is connected to the current mirror circuit 300D formed of the N-type transistor 124A and the N-type transistor 124B.

The N-type transistor 124A is diode-connected such that one end of the current path of the N-type transistor 124A is connected to the gate of the N-type transistor 124A. The other end of the current path of the N-type transistor 124A and the other end of the current path of the N-type transistor 124B are connected to a ground line, that is, are connected to the ground.

The gate of the N-type transistor 124A is connected to a gate of the N-type transistor 124B. The gates of two N-type transistors 124A, 124B which are connected to each other constitute a node ND1B of the current mirror circuit 300D.

One end of the current path of the P-type transistor 100B is connected to one end of the current path of the N-type transistor 124A, and is also connected to the node ND1B.

A magnitude of a reference current for the current mirror circuit 300D is determined corresponding to a drive state of the P-type transistor 100B. The current mirror circuit 300D outputs an electric current which corresponds to the reference current thereof.

An output node of the current mirror circuit 300D, to be more specific, one end of the current path of the N-type transistor 124B is connected to the node (input node) ND2A of the current mirror circuit 300C, which is connected to the gates of two P-type transistors 123A, 123B. An output current of the current mirror circuit 300D is supplied to the current mirror circuit 300C as a section of a reference current of the current mirror circuit 300C together with an electric current from the transistor 100B of the input section 10.

The current mirror circuit 300E is formed of an N-type transistor 125A and an N-type transistor 125B.

The N-type transistor 125A is diode-connected. One end of a current path of the N-type transistor 125A is connected to a gate of the N-type transistor 125A. The other end of the current path of the N-type transistor 125A is connected to the ground.

The gate of the N-type transistor 125A is connected to a gate of the N-type transistor 125B. The other end of a current path of the N-type transistor 125B is connected to the ground.

One end of the current path of the N-type transistor 125A is connected to one end of the current path of the P-type transistor 121B. An output current of the current mirror circuit 300A is supplied to the current mirror circuit 300E as a reference current for the current mirror circuit 300E.

An output node of the current mirror circuit 300E is connected to an output node of the current mirror circuit 300C. One end of a current path of the N-type transistor 125B is connected to one end of the current path of the P-type transistor 123B.

The output nodes of two current mirror circuits 300C, 300E which are connected to each other constitute the output section 20 of the amplifier circuit.

Using electric currents from the current mirror circuits 300C, 300E based on a difference in signals inputted into the input sections 10, 11 when the signals Vin, VREF are inputted into the differential input sections 10, 11, the N-type transistor 125B and the P-type transistor 123B perform a push-pull operation so that the output signal Vout of the amplifier circuit 1 is generated.

In this manner, the input signal Vin is differentially amplified by the differential input sections and the plurality of current mirror circuits connected in multiple stages, both of which the amplifier circuit 1 of this embodiment includes, and an amplified signal is outputted as the output signal Vout.

Hereinafter, unless it is necessary to distinguish from each other the respective current mirror circuits 300A, 300B, 300C, 300D, 300E which constitute the output generation circuit 30 of the amplifier circuit 1, each current mirror circuit 300A, 300B, 300C, 300D, 300E is expressed as a current mirror circuit 300.

In the amplifier circuit 1 of this embodiment, current sources 190A, 190B, 190C, 190D are connected to inner nodes (connection nodes) which connect the input sections 10, 11 with the output generation circuits (current mirror circuits) 300A, 300B, 300C, 300D.

The current source 190A is connected to a connection node between the N-type transistor 100A of the first input section 10 and the current mirror circuit 300A.

The current source 190A is connected to the node ND1A through a current path of an N-type transistor 191A which functions as a switching element. An input node of the current source 190A is connected to the node ND1A through the current path of the N-type transistor 191A. An output node of the current source 190A is connected to the ground line.

A conductive state between the current source 190A and the node ND1A is controlled by turning on or off the N-type transistor 191A. The turning on or off of the N-type transistor 191A is controlled in response to a control signal CT1 supplied to a gate of the N-type transistor 191A.

The current source 190B is connected to the connection node ND2A between the N-type transistor 101A of the second input section 11 and the current mirror circuit 300C through a current path of an N-type transistor 191B. An input node of the current source 190B is connected to the node ND2A through the current path of the N-type transistor 191B. An output node of the current source 190B is connected to the ground line.

A conductive state between the current source 190B and the node ND2A is controlled by turning on or off the N-type transistor 191B. The turning on or off of the N-type transistor 191B is controlled in response to the control signal CT1 supplied to a gate of the N-type transistor 191B.

When the current source 190A is brought into a state where the current source 190A is conductive with the node ND1A through the N-type transistor 191A in an ON state, the node ND1A is discharged. When the current source 190B is brought into a state where the current source 190B is conductive with the node ND2A through the N-type transistor 191B in an ON state, the node ND2A is discharged.

The current source 190C is connected to the connection node ND1B between the P-type transistor 100B of the first input section 10 and the current mirror circuit 300D through a current path of a P-type transistor 196A. An output node of the current source 190C is connected to the node ND1B through the current path of the P-type transistor 196A. An input node of the current source 190C is connected to the power source line.

A conductive state between the current source 190C and the node ND1B is controlled by turning on or off the P-type transistor 196A. The turning on or off of the P-type transistor 196A is controlled in response to a control signal CT2 supplied to a gate of the P-type transistor 196A.

The current source 190D is connected to the connection node ND2B between the P-type transistor 101B of the second input section 11 and the current mirror circuit 300B through a current path of a P-type transistor 196B. An output node of the current source 190D is connected to the node ND2B through the current path of the P-type transistor 196B. An input node of the current source 190D is connected to the power source line.

A conductive state between the current source 190D and the node ND2B is controlled by turning on or off the P-type transistor 196B. The turning on or off of the P-type transistor 196B is controlled in response to the control signal CT2 supplied to a gate of the P-type transistor 196B.

When the current source 190C is brought into a state where the current source 190C is conductive with the node ND1B through the P-type transistor 196A in an ON state, the node ND1B is charged. When the current source 190D is brought into a state where the current source 190D is conductive with the node ND2B through the P-type transistor 196B in an ON state, the node ND2B is charged.

The respective current sources 190A, 190B, 190C, 190D output electric currents of predetermined current values.

For example, before the amplifier circuit 1 of this embodiment receives the input signal Vin, the nodes between the input sections 10, 11 and the current mirror circuits 300A, 300B, 300C, 300D are brought into either a discharged state or a charged state depending on a characteristic (a conductive type of the transistor, for example) of the element connected to the node.

In this manner, when the amplifier circuit 1 is shifted to a drive state from a standby state, depending on the current source 190A, 190B, 190C, 190D, the node in the current mirror circuit formed of the N-type transistors is brought into a discharged state in advance, and the node in the current mirror circuit formed of the P-type transistors is brought into a charged state in advance.

Hereinafter, unless it is necessary to distinguish the current sources 190A, 190B, 190C, 190D which bring the nodes ND1A, ND2A, ND1B, ND2B into a discharged state or a charged state from each other, each current source 190A, 190B, 190C, 190D is expressed as the current source 190.

The transistors 191A, 191B for controlling the discharge of the nodes ND1A, ND2A may be controlled by a common control signal CT1, or may be driven by control signals which are independent from each other. In the same manner, the transistors 196A, 196B for controlling the charge of the nodes ND1B, ND2B may be controlled by a common control signal CT2, or may be driven by control signals which are independent from each other.

In the amplifier circuit 1 of this embodiment, the current sources 190 are connected to the connection sections between the input sections 10, 11 and the current mirror circuits (output generation circuits) 300A, 300B, 300C, 300D. Due to such a constitution, when the amplifier circuit 1 is shifted to a drive state from a standby state, potentials of the inner nodes of the amplifier circuit 1, that is, the potentials of the nodes between the input sections 10, 11 and the current mirror circuits 300A, 300B, 300C, 300D, for example, are controlled by the current sources 190.

As a result, in the amplifier circuit 1 of this embodiment, before the amplifier circuit 1 receives the input signal Vin (before the operation of the amplifier circuit 1 is started), the nodes in the current mirror circuits 300A, 300C, 300D, 300D can be brought into either a discharged state or a charged state in advance and hence, it is possible to suppress a delay in the operation of the amplifier circuit at the time of shifting the operation of the amplifier circuit.

Due to such a constitution, in the amplifier circuit of this embodiment, it is possible to shorten a time from a point of time that the amplifier circuit receives the input signal Vin to a point of time that the generation of the output signal Vout is started and hence, the amplifier circuit can be operated at a high speed.

As set forth above, according to the semiconductor circuit of this embodiment, the operational characteristics of the circuit can be enhanced.

### (2) Operational Example

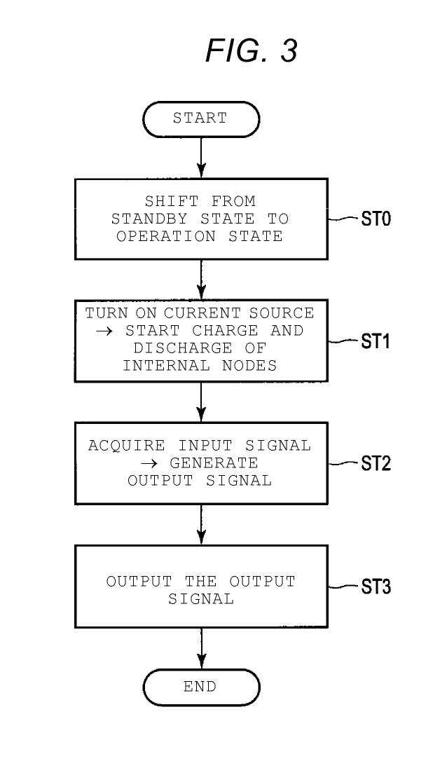

The operation of the amplifier circuit of this embodiment is explained in conjunction with FIG. 3. The explanation of the operation of the amplifier circuit of this embodiment is made also in conjunction with FIG. 2 when necessary.

FIG. 3 is a flowchart for explaining the operation of the amplifier circuit of this embodiment.

As shown in FIG. 3, for example, when a power source voltage or a drive voltage is applied to a semiconductor integrated circuit including the amplifier circuit 1 of this embodiment or when an operation of returning the amplifier circuit 1 from a sleep state is started, the amplifier circuit 1 of this embodiment is shifted to an operating state from a standby state (step ST0). The operation of the amplifier circuit 1 of this embodiment is started as a result of this shifting.

In the amplifier circuit 1, the current sources 190 which are connected to the inner nodes (connection nodes) connecting the input sections 10, 11 with the internal circuits (output generation circuits) 300 to each other are brought into an ON state. As a result of this operation, a conductive state is established between the current sources 190 and the inner nodes of the amplifier circuit 1 so that the connection nodes between the input sections 10, 11 and the current mirror circuits 300 which function as an output generation circuit are charged or discharged by the current sources 190 (step ST1).

In a state where the drive voltage V1 is applied to the amplifier circuit 1 of the embodiment shown in FIG. 2 and before the input signal Vin and the reference signal VREF are inputted into the amplifier circuit 1, the control signal CT1 of an “H” level is inputted into the gate of the N-type transistor 191A to control the connection between the current source 190A and the inner node ND1A and into the gate of the N-type transistor 191B to control the connection between the current source 190B and the inner node ND2A respectively. Accordingly, the N-type transistor 191A is turned on so that the current source 190A and the node ND1A are made conductive with each other, and the N-type transistor 191B is turned on so that the current source 190B and the node ND2A are made conductive with each other.

Accordingly, the node ND1A in the current mirror circuit 300A on an input signal Vin side is brought into a discharged state by the current source 190A. The node ND2A in the current mirror circuit 300C on a reference signal VREF side is brought into a discharged state by the current source 190B.

Substantially simultaneous with the inputting of the control signal CT1, the control signal CT2 of an “L” level is inputted into the gates of the P-type transistors 196A, 196B to control the connection between the current source 190C and the node ND1B and the connection between the current source 190D and the node ND2B respectively. The P-type transistor 196A, 196B are turned on so that the current source 190C and the node ND1B are made conductive with each other and the current source 190D and the node ND2B are made conductive with each other.

Accordingly, the node ND1B in the current mirror circuit 300D on the input signal Vin side is brought into a charged state by an electric current supplied to the node from the current source 190C. The node ND2B in the current mirror circuit 300B on the reference signal VREF side is brought into a charged state by an electric current supplied from the current source 190D.

In this manner, in the amplifier circuit 1 of this embodiment, during a period up to a point that the input signal Vin is inputted into the amplifier circuit from a standby state, the nodes ND1A, ND2A, ND1B, ND2B are respectively charged or discharged by the current sources 190 such that the connection nodes ND1A, ND2A, ND1B, ND2B between the input sections 10, 11 and the current mirror circuits 300A, 300B, 300C, 300D are shifted to certain potentials.

The input signal Vin and the reference signal VREF are inputted into the amplifier circuit 1. The amplifier circuit of this embodiment acquires the input signal Vin, and generates the output signal Vout by the amplification of a difference between the input signal Vin and the reference signal VREF (step ST2).

When the input signal Vin is of an “H” level, the amplifier circuit 1 of this embodiment is driven as follows.

A potential of the input signal Vin of an “H” level (3.3V, for example) is higher than a potential of the reference signal VREF (1.65V, for example).

Accordingly, an output current of the N-type transistor 100A into which the input signal Vin of an “H” level is inputted is increased, and an output current of the N-type transistor 101A into which the reference signal VREF is inputted is decreased. An output current of the P-type transistor 100B into which the input signal Vin of an “H” level is inputted becomes smaller than an output current of the P-type transistor 101B into which the reference signal VREF is inputted.

In this manner, the N-type transistors 100A, 101A and the P-type transistors 100B, 101B of the input section 10, 11 are driven in a differential state.

Respective electric currents from the transistors 100A, 100B, 101A, 101B of the input sections 10, 11 are supplied to the current mirror circuits 300A, 300D, 300C, 300B connected to the respective transistors 100A, 100B, 101A, 101B as reference currents for the current mirror circuits.

When a voltage value of the input signal Vin is larger than a voltage value of the reference signal VREF, an electric current larger than an electric current which is supplied to the current mirror circuit 300C is supplied to the current mirror circuit 300A by the N-type transistor 100A. Further, an electric current larger than an electric current which is supplied to the current mirror circuit 300D is supplied to the current mirror circuit 300B by the P-type transistor 101B.

To the node ND1A in the current mirror circuit 300A, in addition to an electric current from the N-type transistor 100A, an output current of the current mirror circuit 300B is supplied as a reference current. To the node ND2A in the current mirror circuit 300C, in addition to an electric current from the N-type transistor 101A, an output current of the current mirror circuit 300D is supplied as a reference current.

Due to such an operation, potentials of the nodes ND1A, ND2B, ND2A, ND1B in the respective current mirror circuits 300A, 300B, 300C, 300D are changed by electric currents of the transistors 100A, 101B, 101A, 100B of the input sections 10, 11. Each current mirror circuit 300 outputs an electric current corresponding to a magnitude of the supplied reference current.

In this embodiment, before the amplifier circuit 1 is brought into a drive state from a standby state (before sampling of the input signal Vin is started), the nodes ND1A, ND2A in the current mirror circuits 300A, 300C are discharged, and the nodes ND2B, ND1B in the current mirror circuits 300B, 300D are charged. Accordingly, a period can be shortened during which potentials of the nodes ND1A, ND1B, ND2A, ND2B are shifted by electric currents of the transistors 100A, 100B, 101A, 101B of the input sections 10, 11.

The current mirror circuit 300A outputs an output current corresponding to a magnitude of an electric current of the N-type transistor 100A which forms the differential input section 10 and a magnitude of an output current of the current mirror circuit 300B. The electric current from the current mirror circuit 300A is outputted to the current mirror circuit 300E. The electric current from the current mirror circuit 300A is supplied to one end of the current path of the N-type transistor 125A in a diode connection and to the gate of the N-type transistor 125A in the current mirror circuit 300E from one end of the current path of the P-type transistor 121B.

The current mirror circuit 300E outputs an electric current using the electric current from the current mirror circuit 300A as a reference current.

The current mirror circuit 300C outputs an electric current corresponding to a magnitude of an electric current of the N-type transistor 101A which forms the differential input section 11 and a magnitude of an output current of the current mirror circuit 300D.

A potential of the output section 20 is changed by an output current of the current mirror circuit 300C and an output current of the current mirror circuit 300E.

When a voltage value of the input signal Vin is larger than a voltage value of the reference signal VREF, an electric current which flows through the N-type transistor 100A of the first input section 10 is larger than an electric current which flows through the N-type transistor 101A of the second input section 11. That is, an electric current outputted from the P-type transistor 123B of the current mirror circuit 300C is smaller than an electric current outputted from the N-type transistor 125B of the current mirror circuit 300E.

As a result, due to the push-pull operation of the P-type transistor 123B and the N-type transistor 125B, a potential of the node to which the output section 20 is connected is lowered to a ground voltage from the drive voltage V1.

Accordingly, the output signal Vout of an “L” level is outputted to the outside of the amplifier circuit 1 from the output generation circuit 30 which is constituted of the current mirror circuits in the amplifier circuit 1.

When the input signal Vin is of an “L” level, the amplifier circuit 1 of this embodiment is driven as follows.

A potential of the input signal Vin of an “L” level (0V, for example) is lower than a potential of the reference signal VREF (1.65V, for example).

Accordingly, an electric current of the N-type transistor 100A into which the input signal Vin of an “L” level is inputted is decreased, and an electric current of the N-type transistor 101A into which the reference signal VREF is inputted is increased.

An electric current of the P-type transistor 100B into which the input signal Vin of an “L” level is inputted is larger than an electric current of the P-type transistor 101B into which the reference signal VREF is inputted.

In this case, contrary to a case where the input signal Vin is of an “H” level, an output current of the current mirror circuit 300C is larger than an output current of the current mirror circuit 300E and hence, a potential of the node to which the output section 20 is connected becomes the drive voltage V1.

Accordingly, the output signal Vout of an “H” level is outputted to the outside of the amplifier circuit 1 from the output generation circuit 30 formed of the current mirror circuits in the amplifier circuit 1.

In this manner, in the amplifier circuit 1 of a current mirror circuit type according to this embodiment, the output signal Vout is generated by the amplification of a differential between the input signal Vin and the reference signal VREF

The generated output signal Vout is outputted to the outside of the amplifier circuit 1 from the output section 20 of the amplifier circuit 1 (step ST3).

The amplifier circuit 1 of this embodiment is driven as follows.

As shown in FIG. 3, when the amplifier circuit 1 is shifted to an operating state from a standby state, by the current sources 190 which are connected to the connection nodes between the input sections 10, 11 and the current mirror circuits 300 (output generation circuit 30), the connection nodes are charged or discharged before an input signal is inputted into the amplifier circuit 1 (before the amplifier circuit 1 generates an output signal).

Due to such a constitution, when the amplifier circuit 1 is shifted to a drive state from a standby state, a time until the nodes between the input sections 10, 11 and the current mirror circuits 300 of the amplifier circuit 1 reach predetermined potentials (a time until the generation of the output signal Vout is started) can be shortened and hence, the amplifier circuit 1 can be operated at a high speed.

As set forth above, according to the operation of the semiconductor circuit of this embodiment, the operational characteristics of the semiconductor circuit can be enhanced.

### (3) Application Example

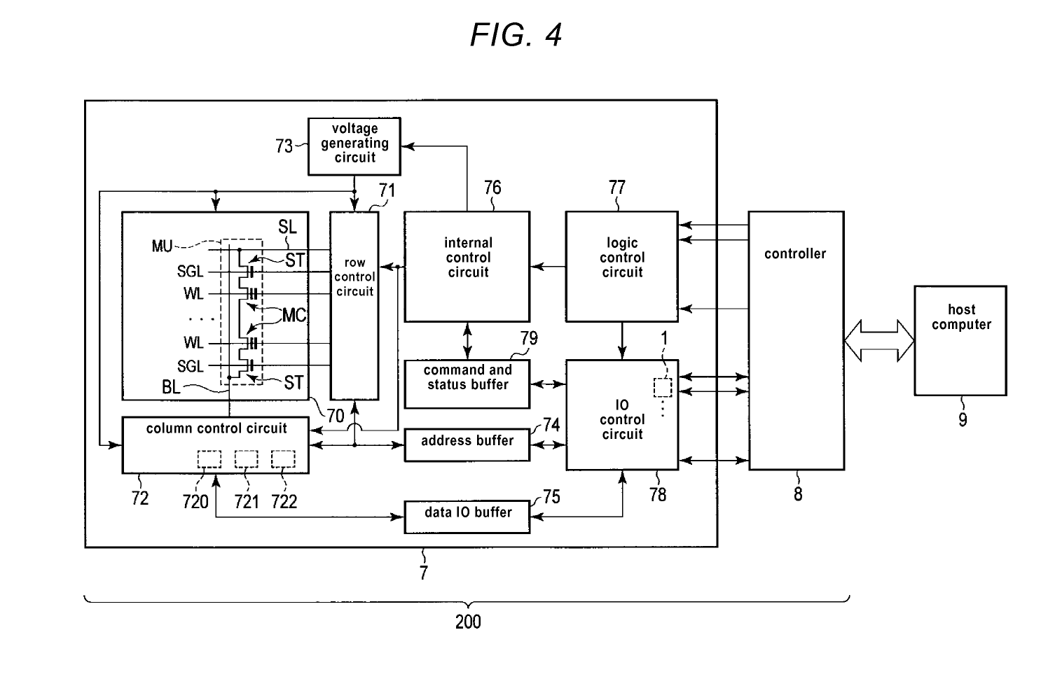

An application example of the amplifier circuit of this embodiment is explained in conjunction with FIG. 4.

For example, the amplifier circuit of this embodiment is used in a semiconductor memory.

FIG. 4 is a block diagram showing components of the semiconductor memory which includes the amplifier circuit of this embodiment. A semiconductor memory 7 of this embodiment is a NAND-type flash memory, for example.

A controller 8 and a host computer 9 are provided outside a chip of the flash memory 7. The controller 8 transmits a control signal (command) to the flash memory 7 based on a data read request or a data write request from the host computer 9 for instructing the flash memory 7 to read data from a memory cell or to write data in the memory cell. The controller 8 and the host computer 9 obtain an operating state of the flash memory 7 by receiving a control signal (status) from the flash memory 7.

For a write, the controller 8 and the host computer 9 transmit, together with the write command, data to be written and an address which indicates rows and columns in which data is to be written into the flash memory 7. For a read, the controller 8 and the host computer 9 receive data read from the flash memory 7 in response to the read command. The controller 8 and the host computer 9 include an address of the read data in the read command.

A storage device (memory system) 200 such as a memory card or a Solid State Drive (SSD) is formed of the flash memory 7 and the controller 8.

In the flash memory 7, a memory cell array 70 includes a plurality of memory cells. A plurality of blocks are set as a control unit in the memory cell array 70. The block indicates a minimum unit of data erasing, for example.

One block includes a plurality of memory cell units MU which are arranged parallel to each other in the row direction.

One memory cell unit MU includes a memory cell string formed of a plurality of memory cells MC, a selection transistor ST connected to one end of the memory cell string, and a selection transistor ST connected to the other end of the memory cell string. In the memory cell string, current paths of the memory cells MC are connected to each other in series along the column direction.

A source line SL is connected to one end of the memory cell unit MU. A bit line BL is connected to the other end of the memory cell unit MU.

The memory cell MC is a field effect transistor having a gate structure which includes a charge storage layer (for example, a floating gate electrode or an insulation film having an electron trap level, or a multilayer film formed of the floating gate electrode and the insulation film). Two memory cells MC arranged adjacent to each other in the column direction are configured such that a source of one memory cell MC is connected to a drain of the other memory cell MC. Because of this configuration, the current paths of the memory cells MC are connected to each other in series thus forming the memory cell string.

Word lines WL extend in the row direction, and each word line WL is connected to gates of the plurality of memory cells MC arranged in common along the row direction.

Selection gate lines SGL extend in the row direction, and each selection gate line SGL is connected to gates of the selection transistors ST which are arranged in common along the row direction.

Each memory cell MC stores data of 1 bit, 2 bits, or more bits that are transmitted from the outside and a magnitude of a threshold voltage (distribution of the threshold voltage) of the transistor is associated with the stored data. Data is collectively written in or read from the memory cells MC connected to the same word line WL. A control unit for controlling a row of the memory cell array 70 in writing data or reading data is referred to as “page”.

A row control circuit 71 controls rows of the memory cell array 70. The row control circuit 71 is connected to the word lines WL and the selection gate lines SGL arranged in the memory cell array 70. The row control circuit 71 selects blocks and pages (word lines WL) based on a row address transmitted from an address buffer 74, and controls the operation (potential) of the word lines WL and the operation (potential) of the selection gate lines SGL. For example, the row control circuit 71 controls potentials of the source lines SL.

A column control circuit 72 controls columns of the memory cell array 70. The column control circuit 72 selects control units set with respect to the column of the memory cell array 70 and controls the operation (potentials) of the bit line BL based on a column address transferred from the address buffer 74. The column control circuit 72 includes a sense amplifier circuit 720, a data latch circuit 721, a column decoder 722 and the like.

The sense amplifier circuit 720 controls the charge and the discharge of the bit line BL, and amplifies and detects a change in potential of the bit line BL.

The data latch circuit 721 temporarily holds data from the outside and data from the memory cell array 70.

The column decoder 722 decodes the column address transmitted from the address buffer 74, and brings a plurality of control units allocated to the bit line which is selected (referred to as “selected bit line”) BL or the column of the memory cell array 70 into an active state.

A voltage generating circuit 73 generates a write voltage, a read voltage, an intermediate potential and a non-selected potential which are applied to each word line WL at the time of performing data writing (program), data reading and data erasing. The voltage generating circuit 73 generates a potential applied to the selection gate line SGL, for example. The potential generated by the voltage generating circuit 73 is transmitted to the row control circuit 71, and is applied to the selected/non-selected word line WL and the selection gate line SGL respectively. The voltage generating circuit 73 generates a potential applied to the column control circuit 72, a potential applied to the source line SL and a potential applied to a well region.

A data input and output buffer 75 functions as an interface for inputting or outputting data. The data input and output buffer 75 temporarily holds data which is inputted thereto from an external device (for example, controller 8 or host computer 9) through an input and output control circuit (I/O control circuit) 78. The data input and output buffer 75 temporarily holds data outputted from the memory cell array 70, and outputs holding data to the outside of the flash memory 7 through the I/O control circuit 78 at a predetermined timing.

The address buffer 74 temporarily holds an address signal inputted thereto through the I/O control circuit 78. The address signal transmitted from the outside is a physical address, for example, and the physical address includes a physical row address and a physical column address.

An internal control circuit 76 manages the operation of the entire flash memory 7. The internal control circuit 76 receives a control signal (command) which is supplied thereto through the I/O control circuit 78. The internal control circuit 76 transmits a control signal indicative of an operating state (status) of the inside of the flash memory 7 to the external devices 8, 9. The command or the status which constitutes a control signal is inputted or outputted between the internal control circuit 76 and the I/O control circuit 78 through a command and status buffer 79.

A logic control circuit 77 receives a control signal (enable signal, for example) transmitted from the outside (a host computer or a controller) such as a Command Latch Enable (CLE) and an Address Latch enable (ALE), and transmits such a control signal to the internal control circuit 76. The logic control circuit 77 outputs the received signal (command or data) to the I/O control circuit 78.

The I/O control circuit 78 controls the operation timing of an operation such as the inputting or outputting of data, the reception of a command or the transmission of a status between the flash memory 7 and the controller 8/host computer 9. The I/O control circuit 78 includes a control unit (interface processing unit) for executing interface processing, for example.

The I/O control circuit 78 is connected to the controller 8 through an I/O terminal and an I/O signal line, for example. The I/O control circuit 78 is connected to the respective circuits 71, 72, 76 in the flash memory 7 through the respective buffers 74, 75, 79. Alternatively, the I/O control circuit 78 may be directly connected to the respective circuits 71, 72, 76.

The amplifier circuit 1 of the embodiment is arranged in the I/O control circuit 78, for example. The amplifier circuit 1 which is used in the flash memory 7, for example, differentially amplifies a signal transmitted from the outside (for example, controller 8) as the input signal Vin, and outputs such a signal to a circuit in the flash memory 7 as the output signal Vout. The amplifier circuit 1 of this embodiment may be used as an amplifier circuit for outputting a signal to an external device from the flash memory 7. The amplifier circuit 1 of the embodiment may be used in a circuit such as the column control circuit 72 or the voltage generating circuit 73 other than the I/O control circuit 78 in the flash memory 7.

As described above, the amplifier circuit 1 of this embodiment is applicable to a semiconductor memory such as a NAND-type flash memory, for example.

The amplifier circuit 1 of this embodiment is applicable to a flash memory (an NOR-type flash memory or an AND-type flash memory, for example) other than the NAND-type flash memory. The amplifier circuit 1 of this embodiment is also applicable to a DRAM, an SRAM, an MRAM, a PCRAM or an ReRAM. A memory which includes the amplifier circuit 1 of this embodiment may have a memory cell array having the three dimensional structure. For example, in the memory cell array having the three dimensional structure, a memory cell is a vertical type transistor which includes a charge storage layer. A semiconductor memory which includes the amplifier circuit 1 of this embodiment may have a cross-point type memory cell array. The amplifier circuit 1 of this embodiment is applicable to a semiconductor integrated circuit, an image sensor, a system LSI or the like which is formed of a logic circuit and an analogue circuit.

As described above, the semiconductor integrated circuit which includes the amplifier circuit 1 of this embodiment can perform inputting and outputting of the data and signals at a high speed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor circuit comprising:
a first input section into which a first input signal is inputted;
a second input section into which a second input signal is inputted;
an output generation circuit which is connected to the first and second input sections and generates an output signal based on the first and second input signals;
an output section which outputs the output signal; and
a plurality of current sources which are respectively connected to a connection node between the first input section and the output generation circuit and a connection node between the second input section and the output generation circuit.

2. The semiconductor circuit according to claim 1, wherein the connection nodes are charged or discharged by the current sources before the first input signal is inputted into the first input section.

3. The semiconductor circuit according to claim 2, wherein the first and second input sections form a differential circuit, and
the output generation circuit includes a plurality of current mirror circuits.

4. The semiconductor circuit according to claim 1, wherein
the first input section includes a first transistor of a first conductive type having a gate into which the first input signal is inputted, and a second transistor of a second conductive type having a gate into which the first input signal is inputted, and
the second input section includes a third transistor of the first conductive type having a gate into which the second input signal is inputted, and a fourth transistor of the second conductive type having a gate into which the second input signal is inputted.

5. The semiconductor circuit according to claim 4, wherein
the output generation circuit includes first, second, third, fourth, and fifth current mirror circuits,
a current path of the first transistor is connected to the first current mirror circuit which includes a transistor of the second conductive type,
a current path of the second transistor is connected to the second current mirror circuit which includes a transistor of the first conductive type,
a current path of the third transistor is connected to the third current mirror circuit which includes a transistor of the second conductive type, and
a current path of the fourth transistor is connected to the fourth current mirror circuit which includes a transistor of the first conductive type,
an output node of the second current mirror circuit is connected to an input node of the third current mirror circuit,
an output node of the fourth current mirror circuit is connected to an input node of the first current mirror circuit,
an output node of the first current mirror circuit is connected to an input node of the fifth current mirror circuit which includes a transistor of the first conductive type, and
the output section is connected to a connection node between an output node of the third current mirror circuit and an output node of the fifth current mirror circuit.

6. The semiconductor circuit according to claim 5, wherein
the current sources include first, second, third, and fourth current sources,
a connection node between the first current mirror circuit and the first transistor is discharged by the first current source,
a connection node between the second current mirror circuit and the second transistor is charged by the second current source,
a connection node between the third current mirror circuit and the third transistor is discharged by the third current, and
a connection node between the fourth current mirror circuit and the fourth transistor is charged by the fourth current source.

7. The semiconductor circuit according to claim 6, wherein
the first transistor and the third transistor form a first differential circuit, and
the second transistor and the fourth transistor form a second differential circuit.

8. A semiconductor memory comprising:
a memory cell array; and
an input and output control circuit interfaced with an external controller to receive commands to read data from the memory cell array and write data to the memory cell array, the input and output control circuit comprising an amplifier circuit that includes:
a first input section into which a first input signal is inputted;
a second input section into which a second input signal is inputted;
an output generation circuit which is connected to the first and second input sections and generates an output signal based on the first and second input signals;
an output section which outputs the output signal; and
a plurality of current sources which are respectively connected to a connection node between the first input section and the output generation circuit and a connection node between the second input section and the output generation circuit.

9. The semiconductor memory according to claim 8, wherein the connection nodes are charged or discharged by the current sources before the first input signal is inputted into the first input section.

10. The semiconductor memory according to claim 9, wherein the first and second input sections form a differential circuit, and
the output generation circuit includes a plurality of current mirror circuits.

11. The semiconductor memory according to claim 8, wherein
the first input section includes a first transistor of a first conductive type having a gate into which the first input signal is inputted, and a second transistor of a second conductive type having a gate into which the first input signal is inputted, and
the second input section includes a third transistor of the first conductive type having a gate into which the second input signal is inputted, and a fourth transistor of the second conductive type having a gate into which the second input signal is inputted.

12. The semiconductor memory according to claim 11, wherein
the output generation circuit includes first, second, third, fourth, and fifth current mirror circuits,
a current path of the first transistor is connected to the first current mirror circuit which includes a transistor of the second conductive type,
a current path of the second transistor is connected to the second current mirror circuit which includes a transistor of the first conductive type,
a current path of the third transistor is connected to the third current mirror circuit which includes a transistor of the second conductive type, and
a current path of the fourth transistor is connected to the fourth current mirror circuit which includes a transistor of the first conductive type,
an output node of the second current mirror circuit is connected to an input node of the third current mirror circuit,
an output node of the fourth current mirror circuit is connected to an input node of the first current mirror circuit,
an output node of the first current mirror circuit is connected to an input node of the fifth current mirror circuit which includes a transistor of the first conductive type, and
the output section is connected to a connection node between an output node of the third current mirror circuit and an output node of the fifth current mirror circuit.

13. The semiconductor memory according to claim 12, wherein
the current sources include first, second, third, and fourth current sources,
a connection node between the first current mirror circuit and the first transistor is discharged by the first current source,
a connection node between the second current mirror circuit and the second transistor is charged by the second current source,
a connection node between the third current mirror circuit and the third transistor is discharged by the third current, and
a connection node between the fourth current mirror circuit and the fourth transistor is charged by the fourth current source.

14. The semiconductor memory according to claim 13, wherein
the first transistor and the third transistor form a first differential circuit, and
the second transistor and the fourth transistor form a second differential circuit.

15. A method of operating an amplifier circuit having a first input section into which a first input signal is inputted, a second input section into which a second input signal is inputted, an output generation circuit which is connected to the first and second input sections and generates an output signal based on the first and second input signals, and an output section which outputs the output signal, the method comprising:
charging a first connection node between the first input section and the output generation circuit and a second connection node between the second input section and the output generation circuit; and
discharging a third connection node between the first input section and the output generation circuit and a fourth connection node between the second input section and the output generation circuit.

16. The method according to claim 15, wherein
the output generation circuit includes first, second, third, fourth, and fifth current mirror circuits, and
the first, second, third, and fourth connection nodes are respectively between the first input section and the first mirror circuit, between the second input section and the third mirror circuit, between the first input section and the second mirror circuit, and between the second input section and the fourth mirror circuit.

17. The method according to claim 16, wherein the output signal is generated at a connection node between an output node of the third current mirror circuit and an output node of the fifth current mirror circuit.

18. The method according to claim 16, wherein
the first, second, third, and fourth connection nodes are respectively connected to first, second, third, and fourth current sources through first, second, third, and fourth transistors.

19. The method according to claim 18, wherein the first and second transistors are controlled with a first control signal, and the third and fourth transistors are controlled with a second control signal.

20. The method according to claim 15, wherein the charging and discharging are carried out when the amplifier circuit is returned to an operating state from a sleep state.
